(19) United States
(12) Patent Application Publication
(10) Pub. No.: US 2006/0223227 A1
(43) Pub. Date: Oct. 5, 2006

(54) Molding method for foldover package

(75) Inventors: Yoichi Kubota, Pleasanton, CA (US); Ellis Chau, San Jose, CA (US); Teck-Gyu Kang, San Jose, CA (US); Jae M. Park, San Jose, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/098,650

(22) Filed: Apr. 4, 2005

(51) Int. Cl. H01L 21/00

(52) U.S. Cl. 438/106

(57) ABSTRACT

A method of making a microelectronic assembly including the steps of depositing one or more microelectronic elements onto a flexible substrate and folding the substrate so that a first region of the substrate forms a first run and a second region of the substrate forms a second run overlaying the first run. The first run and the second run form a pocket therebetween. While temporarily maintaining the folded structure, providing an encapsulant material into the pocket. The encapsulant material is next cured, so that the cured encapsulant material holds the flexible substrate in the folded state.

### BACKGROUND OF THE INVENTION

Microelectronic elements such as semiconductor chips typically are provided in packages which provide physical and chemical protection for the semiconductor chip or other microelectronic elements. Such a package typically includes a package substrate such as a small circuit panel formed from a dielectric material and having electrically conductive terminals thereon. The chip is mounted on the panel and electrically connected to the terminals of the package substrate. Typically, the chip and portions of the substrate are covered by an encapsulant or overmolding, so that only the terminal-bearing outer surface of the substrate remains exposed. Such a package can be readily shipped, stored and handled. The package can be mounted to a larger circuit panel such as a circuit board using standard mounting techniques, most typically surface-mounting techniques. Considerable effort has been devoted in the art to making such packages smaller, so that the packaged chip occupies a smaller area on the circuit board. For example, packages referred to as chip-scale packages occupy an area of the circuit board equal to the area of the chip itself, or only slightly larger than the area of the chip itself. However, even with chip-scale packages, the aggregate area occupied by several packaged chips is greater than or equal to the aggregate area of the individual chips.

It has been proposed to provide “stacked” packages, in which a plurality of chips is mounted one above the other in a common package. This common package can be mounted on an area of the circuit panel, which may be equal to or just slightly larger than the area typically required to mount a single package containing a single chip. The stacked package approach conserves space on the circuit panel. Chips or other elements, which are functionally related to one another, can be provided in a common stacked package. The package may incorporate interconnections between these elements. Thus, the main circuit panel to which the package is mounted need not include the conductors and other elements required for these interconnections. This, in turn, allows use of a simpler circuit panel and, in some cases, allows the use of a circuit panel having fewer layers of metallic connections, thereby materially reducing the cost of the circuit panel. Moreover, the interconnections within a stacked package often can be made with lower electrical impedance and shorter signal propagation delay times than comparable interconnections between individual packages mounted on a circuit panel. This, in turn, can increase the speed of operation of the microelectronic elements within the stacked package as, for example, by allowing the use of higher clock speeds in signal transmissions between these elements.

One form of stacked packages, which has been proposed heretofore, is sometimes referred to as a “ball stack.” A ball stack package includes two or more individual units. Each unit incorporates a unit substrate similar to the package substrate of an individual package, and one or more microelectronic elements mounted to the unit substrate and connected to the terminals on the unit substrate. The individual units are stacked one above the other, with the terminals on each individual unit substrate being connected to terminals on another unit substrate by electrically conductive elements such as solder balls or pins. The terminals of the bottom unit substrate may constitute the terminals of the package or, alternatively, an additional substrate may be mounted at the bottom of the package and may have terminals connected to the terminals of the various unit substrates. Ball stack packages are depicted, for example, in certain preferred embodiments of U.S. Published Patent Applications 2003/0107118 and 2004/0031972, the disclosures of which are hereby incorporated by reference herein.

In another type of stack package sometimes referred to as a fold stack package, two or more chips or other microelectronic elements are mounted to a single substrate. This single substrate typically has electrical conductors extending along the substrate to connect the microelectronic elements mounted on the substrate with one another. The same substrate also has electrically conductive terminals which are connected to one or both of the microelectronic elements mounted on the substrate. The substrate is folded over on itself so that a microelectronic element on one portion lies over a microelectronic element on another portion, and so that the terminals of the package substrate are exposed at the bottom of the folded package for mounting the package to a circuit panel. In certain variants of the fold package, one or more of the microelectronic elements is attached to the substrate after the substrate has been folded to its final configuration. Examples of fold stacks are shown in certain preferred embodiments of U.S. Pat. No. 6,121,676; U.S. Pat. No. 6,765,288; U.S. patent application Ser. No. 10/655,952; U.S. patent application Ser. No. 10/281,550; U.S. patent application Ser. No. 10/640,177; and U.S. patent application Ser. No. 10/654,375, the disclosures of which are hereby incorporated herein by reference. Fold stacks have been used for a variety of purposes, but have found particular application in packaging chips which must communicate with one another as, for example, in forming assemblies incorporating a baseband signal processing chip and radio frequency power amplifier (“RFPA”) chip in a cellular telephone, so as to form a compact, self-contained assembly.

Despite all of these efforts in the prior art, still further improvements would be desirable, especially in the area of reducing the cost and efficiency in the manufacturing of the stacked packages as well as provided a stacked package which has a relatively low profile. In particular, it would be desirable to provide packages having a reduced height.

### SUMMARY OF THE INVENTION

The present invention is directed to a method of making a microelectronic assembly. The method preferably includes folding a substrate having various electrical conductive elements, to form a folded structure and subsequently providing an encapsulant material within the folded structure. The encapsulant material, once cured, maintains the shape of the folded structure.

One method of the present invention includes the steps of depositing one or more microelectronic elements onto a flexible substrate. The substrate is folded so that a first region of the substrate forms a first run and a second region of the substrate forms a second run overlaying the first run. The first run and the second run form a pocket therebetween. While temporarily maintaining the folded structure an encapsulant material is provided into the pocket. The encapsulant material is next cured, wherein the cured encapsulant material holds the flexible substrate in the folded state.

In one embodiment of the present invention, the encapsulant material bonds the microelectronic elements to the second run. The encapsulant material may be the only element bonding the microelectronic elements to the second run.

The step of folding the substrate may include providing a separator element. The separator element is disposed overlying the first region of the substrate. The substrate is folded about the separator element so that at least a portion of the separator element is disposed in the pocket when the substrate is in the folded state.

In one aspect of the present invention, the step of providing the separator element includes providing a mold plate having at least one runner channel and at least one aperture. After the step of folding the substrate, the runner channel is in communication with the pocket through the at least one aperture. The step of providing the encapsulant material includes urging the encapsulant material through the runner channel and the aperture and into the pocket.

The substrate may also include openings and the separator element may include extensions. The folding step in the present invention may include engaging the extensions with the openings.

The mold plate may also include a column and a plurality of branches projecting from the column. At least some of the microelectronic elements are separated from one another by one of the branches of the mold plate. The runner channel may include channels extending within the branches. The at least one aperture also includes apertures disposed within the branches remote from the column.

In one aspect of the present invention, the step of maintaining the substrate in the folded state may include disposing the substrate between opposed mold elements. At least one of the mold elements may include an inlet channel. The step of urging the encapsulant material may further include urging the encapsulant material through the inlet channel and into the runner channel.

A portion of the separator element may remain integral with the microelectronic assembly.

The step of maintaining the substrate in the folded state may also include disposing the substrate in between mold elements.

In one aspect of the present invention the step of providing encapsulant material includes providing at least one aperture extending from a first surface of the substrate to a second surface of the substrate so that the aperture is in communication with the pocket. The encapsulant material is provided into the pocket through the aperture.

The microelectronic elements include front faces having contacts exposed thereon. The microelectronic elements may be deposited on the substrate so that the front faces of the microelectronic elements face the first region or the second region after the folding step.

### BRIEF DESCRIPTION OF THE DRAWINGS

FIG. 1 shows a diagrammatic top view of an apparatus in a stage of a method of making a folded microelectronic assembly in accordance with one embodiment of the present invention;

FIG. 2 shows a side view of the apparatus of FIG. 1 at a later stage in the method;

FIG. 3 shows a side view of the apparatus of FIG. 2 at a later stage of the method;

FIG. 4 shows a top view of FIG. 3;

FIG. 5 shows a side view of the apparatus of FIG. 3 at a later stage of the method;

FIG. 6 shows a perspective view of the apparatus of FIG. 1 at a later stage of the method;

FIG. 7 shows a side view of a stacked microelectronic assembly incorporating a unit of the apparatus shown in FIG. 6;

FIG. 8 shows a side view of a microelectronic element at a stage in an alternate method of the present invention;

FIG. 9 shows a side view of a microelectronic element at a stage in an alternate method of the present invention;

FIG. 10 shows a side view of a microelectronic element at a stage in an alternate method of the present invention;

FIG. 11 shows a top view of a microelectronic element with a separator element;

FIG. 12 illustrates a top view of the microelectronic element of FIG. 11 with an alternate embodiment of a separator element;

FIG. 13 illustrates a perspective view of FIG. 12 at a later stage of assembly;

FIG. 14 illustrates a perspective view of an microelectronic element and apparatus at a stage in an alternate embodiment of the present invention;

FIG. 15 illustrates a perspective view of an alternate embodiment of FIG. 14;

FIG. 16 illustrates a cross-sectional view of an alternate embodiment of a separator element;

FIG. 17 illustrates a side view of a microelectronic element at a stage in an alternate method of the present invention;

FIG. 18 illustrates a side view of the microelectronic element of FIG. 17 at a later stage in the method;

FIG. 19 illustrates a side view of a microelectronic element at a stage in an alternate method of the present invention; and

FIG. 20 illustrates a side view of the microelectronic element of FIG. 19 at a later stage in the method;

### DETAILED DESCRIPTION

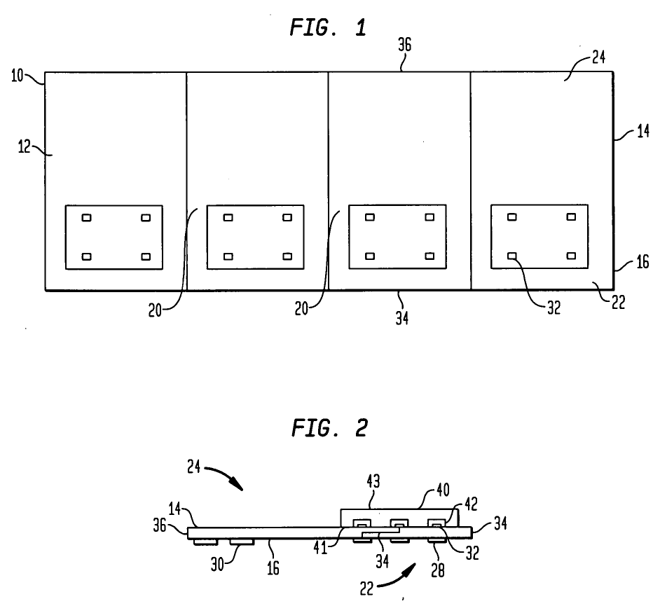

As shown in FIGS. 1 and 2, a method in accordance with one embodiment of the present invention includes providing a flexible substrate 10 incorporating a dielectric layer 12 defining a first or upper surface 14 and a second or lower surface 16. The substrate 10 typically is in the form of a continuous or semicontinuous tape or sheet having a large number of sections 20. Each section 20 may constitute a portion of an individual package at the end of the process and each section 20 preferably includes features that as discussed below, will form part of a single package. Although the various sections 20 are demarcated by lines in FIG. 1 for clarity of illustration, in actual practice the sections do not have visible borders. In addition, the thickness of the flexible substrate 10 shown in FIG. 2, as well as in subsequent figures, has been greatly exaggerated for clarity of illustration.

Substrate 10 further includes a first region 22 adjacent one edge 34 of the substrate and a second region 24 adjacent an opposite edge 36. Preferably each section 20 includes at least a portion of the first region 22 and at least a portion of the second region 24.

Dielectric layer 12 may be a single layer, or may be a laminate including several sublayers. The dielectric layer desirably is formed primarily from a polymeric material such as polyamide, BT resin, epoxy or other dielectric polymers, and may include reinforcing fibers as, for example, glass fibers.

As shown in FIGS. 1 and 2, substrate 10 preferably includes a set of mounting terminals 28 exposed at the lower surface 16 of the substrate, in first region 22 and a set of interconnect terminals 30 exposed at the lower surface 16 of the substrate, in the second region 24. Each section 20 further includes a set of conductive connection elements 32 exposed at the upper surface 14 of the substrate in first region 22. Within each section 20 at least some of the connection elements 32 are electrically connected to at least some of the mounting terminals 28 or at least some of the interconnect terminals 30 or both. Also, at least some of the interconnect terminals 30 of each section 20 are electrically connected to at least some of the mounting terminals 28 in the same section.

In a particular embodiment depicted, terminals 28 and 30 are formed in a layer separate from conductive connection elements 32, these layers being separated from one another by dielectric layer 12 and electrically connected to one another by conductive elements such as vias 34 extending through the dielectric layer. Such an arrangement is commonly referred to as a “two-metal” structure. However, substrate 10 can be formed as a single metal structure with a single metal layer constituting conductive connection elements 32 as well as terminals 28 and 30. For example, such a layer may be disposed on the lower surface 16 of the substrate, with the conductive elements 32 exposed at the upper surface 14 through holes (not shown) in the substrate. Similarly, such a single metal layer may be disposed on the upper surface 14, with the terminals 28 and 30 being exposed at the lower surface 16 through holes (not shown) in the substrate. In still further alternatives, one or more metallic layers constituting the conductive connection elements, the terminals, or both, can be disposed within the thickness of the dielectric layer and exposed through holes through to the appropriate surfaces.

Microelectronic elements 40 are mounted on the upper surface 14 of substrate 10. Preferably each section 20 has one or more of the microelectronic elements mounted thereon.

In particular embodiments illustrated, each section 20 of the substrate bears one microelectronic element. The microelectronic elements shown are bare or unpackaged semiconductor chips, each having a front surface 41 bearing contacts 42 and an oppositely-facing rear surface 43, mounted in a face-down orientation, with contacts 42 of the chip connected to the conductive connection elements 32 of the substrate as, for example, by bonding the contacts to the conductive mounting elements using a bonding material such as a solder. However, other techniques can be employed. For example, each microelectronic element 40 may be a packaged microelectronic element incorporating a packaged substrate (not shown) with terminals thereon, the terminals being connected to the conductive connection elements 32 on the substrate 10. An overmolding (not shown) may cover the exposed surfaces of each microelectronic element 40. In other embodiments, the overmolding is omitted.

In still other variants, techniques such as isotropic conductive adhesives can be employed. The microelectronic element 40 within each section 20 of the substrate is electrically connected through the conductive connection elements 32 of that section 20 to at least some of the mounting terminals 28, to at least some of the interconnect terminals 30 of the same section or both. Microelectronic elements 40 may be mounted on the substrate using conventional techniques, either as part of the assembly process described herein or in a separate operation used to prepare the substrate.

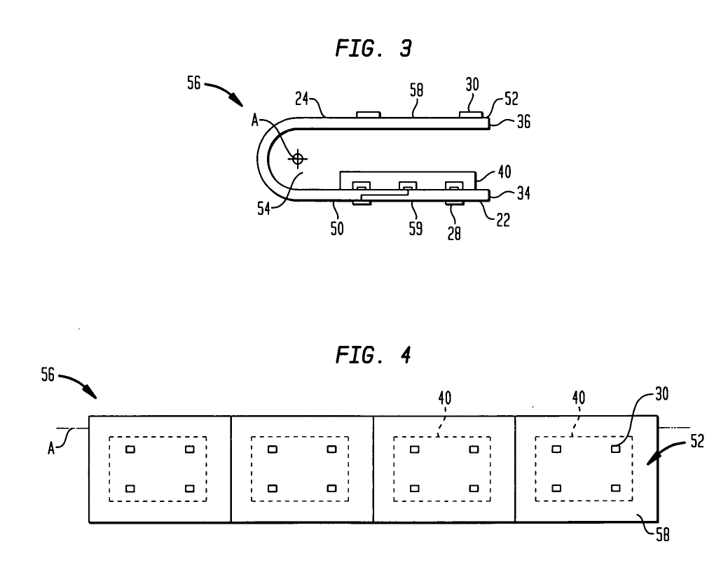

As shown in FIGS. 3 and 4, once the microelectronic elements 40 are positioned correctly on the substrate and all the required electrical connections are complete, the flexible substrate 10 is then folded back upon itself so that portions of the upper surface 14 in the second region 24 face the microelectronic elements 40. As already discussed, one example of a method of folding a substrate to form a fold stack is shown in certain preferred embodiments of U.S. Pat. No. 6,121,676, the disclosure of which is hereby incorporated by reference herein. By placing the substrate in a folded state as shown in FIGS. 3 and 4, the first region 22 forms a first run 50 and the second region 24 forms a second run 52. The second run overlies the first run so as to form a pocket 54 (FIG. 3) therebetween. Microelectronic elements 40 are disposed within pocket 54 and thus positioned between first run 50 and second run 52.

The substrate may be folded by pivoting second region 24 about axis A so that edge 36 of substrate 10 is brought into proximity to edge 34 of the substrate. Once the substrate 10 has been folded upon itself, interconnect terminals 30 are exposed at a top surface 58 of folded structure 56 and mounting terminals 28 are exposed at a bottom surface 59 of the folded structure. Microelectronic elements 40 are shown in hidden view in FIG. 4, as second run 52 overlies them.

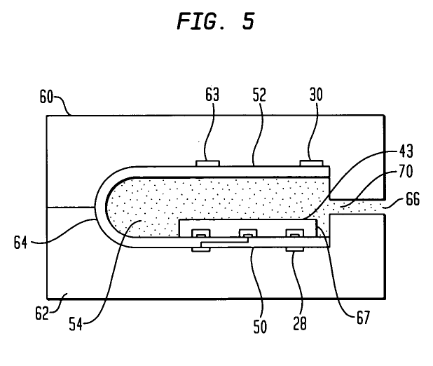

The substrate may be temporarily maintained in its folded state, as for example by first mold element 60 and second mold element 62, as shown in FIG. 5. In one method of assembly, folded structure 56 is disposed within cavity 64 created by the joining of the mold elements. Either one or both of the mold elements may include recesses 63 for capturing mounting terminals 28 and interconnect terminals 30 exposed at an exterior 61 of the folded structure. The recesses serve to protect the terminals from being damaged during the assembly process and may be required if the terminals extend outwardly from the exterior of the folded structure.

In one embodiment of the present invention, the joining of first mold element 60 to second mold element 62 preferably forms at least one opening 66 extending therethrough. Opening 66 is preferably disposed adjacent an open end of the folded structure, such as open end 67 of folded structure 56. With opening 66 disposed adjacent open end 67, the aperture is in communication with pocket 54 and provides a pathway to the pocket from outside the folded structure. While maintaining the C-shape of the folded structure with the mold elements, an encapsulant material 70 is introduced into pocket 54 through opening 66. In a preferred embodiment, the encapsulant material 70 is disposed around microelectronic elements 40 and encompasses most or all of the remaining space between first run 50 and second run 52. The encapsulant material 70 flows around the perimeters of the microelectronic elements and flows between the microelectronic elements 40 and second run 52. The encapsulant material may be a material such as a silicon, epoxy, thermoplastic, thermosetting plastic, gel-like material, or similar insulating material. Once the encapsulant material is finished being urged into pocket 54, the encapsulant material is then cured. As used in this disclosure, the term “curing” refers to any process that at least partially stiffens or solidifies a material. The mechanism of curing will depend of the composition of the encapsulant material. For example, a thermoplastic typically is cured by cooling it, whereas thermosets typically cure by chemical reaction, with or without application of heat. Once encapsulant material 70 has cured, the encapsulant material maintains the C-shape of folded structure 56 even after first mold element 60 and second mold element 62 are removed from the assembly. The encapsulant material maintains the shape of the folded structure by bonding second run 62 to first run 60 or bonding microelectronic elements 40 to second run 62 or both.

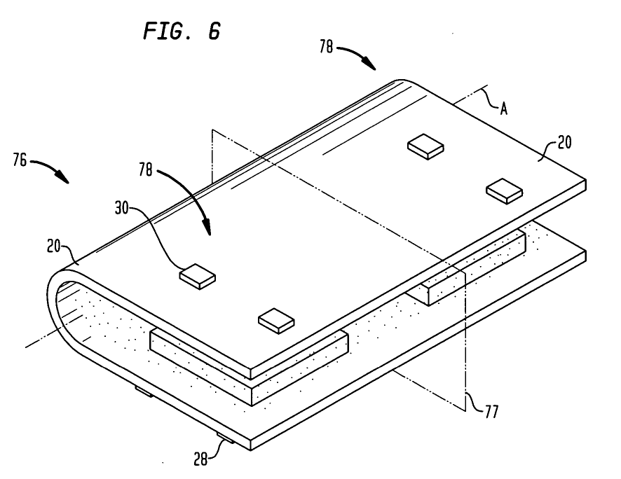

After the second run 62 has been bonded relative to first run 60, the mold elements 60, 62 may be removed from folded structure 56 leaving a completed microelectronic assembly 76, as shown in FIG. 6. Although microelectronic assembly 76 is shown having only two microelectronic elements 40 and two sections 20 for ease of illustration, microelectronic assembly may consist of any number of microelectronic elements and sections including just one microelectronic element and one section. If required, microelectronic assembly 76 may be severed into individual units 78 each including one section 20, such as by cutting along plane 77 transverse to fold axis A, as shown in FIG. 6. Each individual unit 78 preferably includes at least a single microelectronic element disposed within a pocket of a folded structure and held between the folded structure by the encapsulant material.

In a preferred embodiment of the present invention, each individual unit 78 includes mounting terminals 28 exposed at the bottom surface 59 of folded structure 56 and interconnect terminals 30 exposed at the top surface 58 of the folded structure.

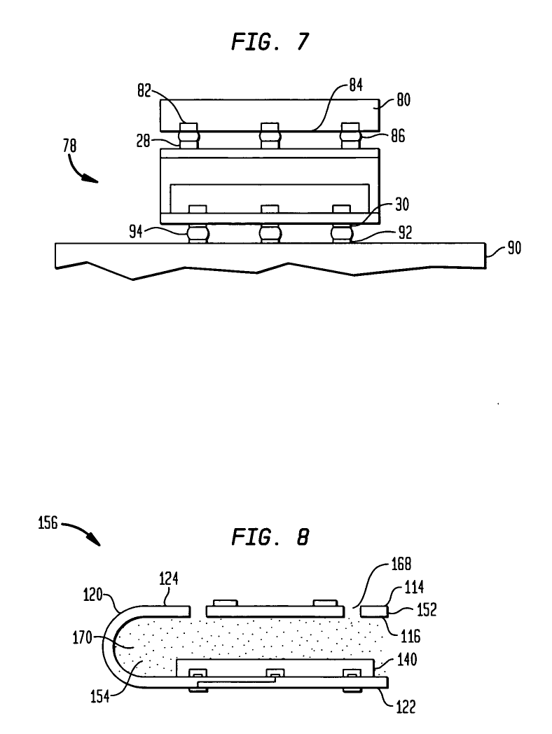

As shown in FIG. 7, a second microelectronic element 80 may overlie and be electrically connected to individual unit 78, such as by solder. In one embodiment, contacts 82 exposed on a front surface 84 of second microelectronic element 80 are electrically connected to interconnect terminals 30 by solder balls 86. The second microelectronic element 80 may consist of an unpackaged or bare semiconductor chip as well as various packaged microelectronic assemblies. Additionally, folded microelectronic assemblies, as exemplified herein, may be stacked one on top of another. Also, as shown in FIG. 7, individual units 78 of folded structure 70 may be attached and electrically connected to a circuit panel 90 or additional microelectronic element by methods known in the art. In one embodiment, as shown in FIG. 7, mounting terminals 28 of individual unit 78 are electrically connected to contact pads 92 of circuit panel 90 by solder balls 94.

As discussed above, a temporary holding fixture such as the mold retains the substrate in its folded condition from the folding step to the time the encapsulant material is sufficiently cured to retain it. Therefore, there is no need to provide a separate layer of adhesive in the rear surface of the microelectronic element to hold the substrate in the folded condition. Eliminating the separate layer of adhesive eliminates the cost and difficulties associated with application of such a layer. Moreover, it is possible to reduce the overall height of the assembly. In FIGS. 3-7, the space between the rear surface 43 of the microelectronic element and the upper run 52 of the folded substrate is greatly exaggerated for clarity of illustration. In actual practice, this space may be as small as desired, and indeed may have a zero thickness so that the rear surface of the microelectronic element abuts the upper run of the substrate eliminating the separate adhesive layer and placing the rear surface of the microelectronic element. Although it is preferred to eliminate the separate layer of adhesive, such a layer can be used if desired.

Moreover, the encapsulant material may be introduced into the mold, and hence into pocket 54 between the runs under pressure. The pressure of the encapsulant material tends to force the upper run 52 against the mold surface, which helps to assure that the interconnect terminals 30 on this run are precisely coplanar with each other

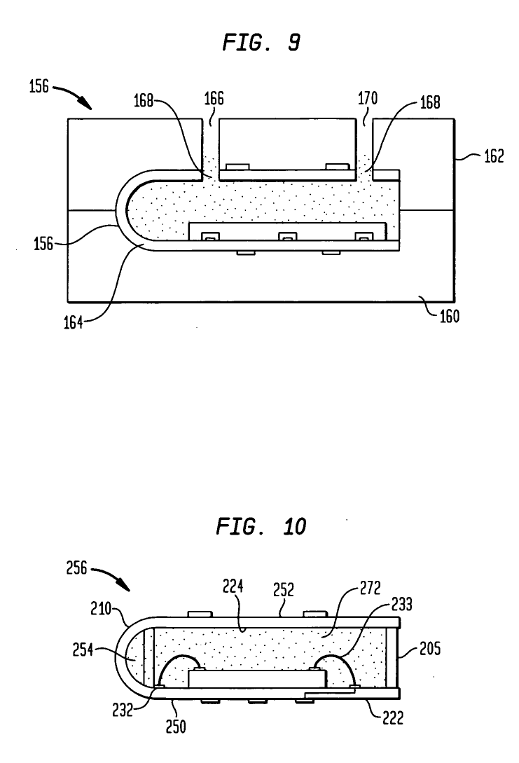

In an alternate embodiment of the present invention, as shown in FIG. 8, substrate 110 may be provided with at least one aperture 168 extending from upper surface 114 to lower surface 116. Substrate 110 is shown in a folded state in FIG. 8 and thus lower surface 114 in the upper run 152 is disposed above upper surface 116. As discussed in conjunction with the prior embodiment, folded structure 156 includes a first run 150 and a second run 152. The second run 152 overlays first run 150 to form a pocket 154 therebetween. While maintaining the C-shape of folded structure 156, an example of which is shown in FIG. 9, an encapsulant material 170 may be introduced through aperture 168 and into pocket 154. Although not shown in the figures, preferably at least one aperture is included within each section 120 of the microelectronic assembly.

As previously alluded to, FIG. 9 illustrates one apparatus used in a method for temporarily maintaining the C-shape of folded structure 156. Here again, the method includes providing a first mold element 160 and a second mold element 162. Folded structure 156 is disposed within cavity 164 formed by the joining of the first mold element to the second mold element. In a preferred embodiment the two mold elements tightly abut one another and tightly capture the folded structure 156 within cavity 164. Either first mold element 160, second mold element 162 or both are provided with at least one opening 166. Similar to opening 66 discussed earlier, openings 166 are adapted for allowing encapsulant material to pass through the mold elements. Openings 166 are preferably aligned with aperture 168 of folded structure 156. Therefore, encapsulant material 170 being provided through openings 166 is able to flow into pocket 154 through aperture 168. Encapsulant material 170 preferably flows over the perimeters of the microelectronic elements and fills most of, if not all of the empty space of pocket 154. As encapsulant material 170 solidifies, microelectronic elements 140 are securely captured between first run 150 and second run 152. Preferably, the solidifying of the encapsulant material bonds the first run to the second run, or the microelectronic elements to the second run or both.

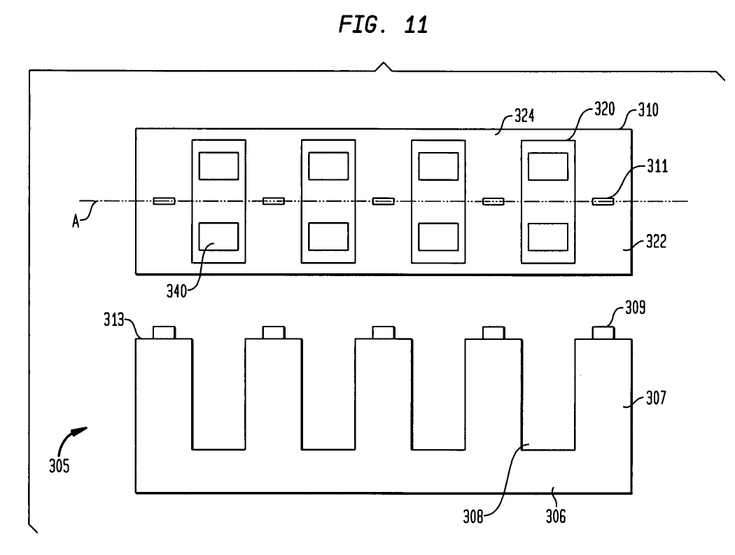

In an alternate embodiment of the present invention, as shown in FIG. 10, a separator element 205 may be incorporated into folded structure 256. Similar to the previous embodiments, after microelectronic elements 240 are positioned and connected, substrate 210 is folded back upon itself so that a portion of the substrate forms first run 250 and another portion forms second run 252. Prior to folding the substrate back upon itself, separator element 205 may be placed overlaying first region 222 or second region 224. Second region 222 is folded about an axis so that first run 250 and second run 252 are formed with cavity 254 being disposed therebetween. In a preferred embodiment, as the second run 224 is folded into position, separator element 205 maintains a predetermined distance between first run 222 and second run 224. In the embodiment of FIG. 10, separator element 205 maintains a minimum distance between the two runs by acting as a spacer between the runs although in alternate embodiments, the separator element may simply be positioned between the runs. Having separator element 205 maintaining a minimum distance between first run 222 and second run 224 may be highly preferred when, for instance, front surface 241 of microelectronic elements 240 faces upwards in the direction of second run 224. This is because front surface 241, as already discussed herein includes contacts 242. At least some of the contacts 242 are interconnected to at least some of the conductive connection elements 232, such as by electrically connecting the two elements using leads 233. In this instance, the integrity of leads 233 and contacts 242 may be compromised if second run 224 were to come in contact with either the contacts or the leads. Therefore, separator element 205 has a height that extends above both the contacts and leads. The second run 224 may only approach the microelectronic elements 240 as far as the separator element 205 permits. Once the second run 224 has been positioned against the separator element 205, encapsulant material 272 may be introduced into pocket 254 in order to maintain the proximity of the second run 224 to the first run 222. As with previous embodiments, substrate 210 may be prepared incorporating a plurality of microelectronic elements 240 and the various components required. After the microelectronic assembly has been completed, individual units may be severed from the microelectronic assembly for ease of use.

In another aspect of the present invention, as shown in FIG. 11, separator element 305 may be designed having a column 306 and a plurality of branches 307. As shown in the figure, branches 307 extend perpendicularly from column 306 and have distal ends 313 remote from column 306. Preferably individual branches 307 are separated by voids 308. Branches 307 may include extensions 309. The extensions extend outwardly from the distal end 313 of branches 307. In this embodiment, substrate 310 includes slots 311 which at least extend partially through substrate 310. Separator 305 is placed so that the branches 307 overlie the first region 322 of substrate 310, and extend between microelectronic elements 340. The distal ends 313 of the branches lie just proximal to the fold axis A, with extensions 309 projecting beyond the fold axis. During the placement of separator element 305 over first region 322 of substrate 310 or during the subsequent folding step, extensions 309 may be engages within slots 311 of the substrate. Once the separator element has been positioned, substrate 310 may be folded back upon itself, as earlier described, so that second region 324 faces microelectronic elements 340 which are disposed in first region 322 and also overlies the separator element. In this embodiment as well, the folded structure is temporarily held in a fixture such as a mold while encapsulant material is injected. The encapsulant material surrounds the microelectronic elements and the separator element. After curing of the encapsulant material, the separator element may be removed and the individual regions may be separated from one another by severing the substrate. Alternatively, the separator element may be left in place during the severing step, so that the separator element is severed along with the substrate. This yields individual units each incorporating portions of the separator element occupying some of the space between the runs of the folded structure. The separator element portions left in the units may further strengthen the units and may provide additional protection against physical damage. Where the separator element is formed from an electrically conductive material, the pieces of the separator element remaining in place in the individual units may provide shielding against electromagnetic interference, and may be electrically connected to conductive elements on the substrate. For example, where the folded substrate includes a ground plane or other shielding structure, the separator element may be connected to that structure so that the ground plane and the pieces of separator element remaining in place cooperatively form a shield substantially surrounding the microelectronic element disposed between the runs of the folded substrate. Also, during the folding and encapsulant injection steps, the separator element helps to control the spacing between the runs, as described above with reference to FIG. 10.

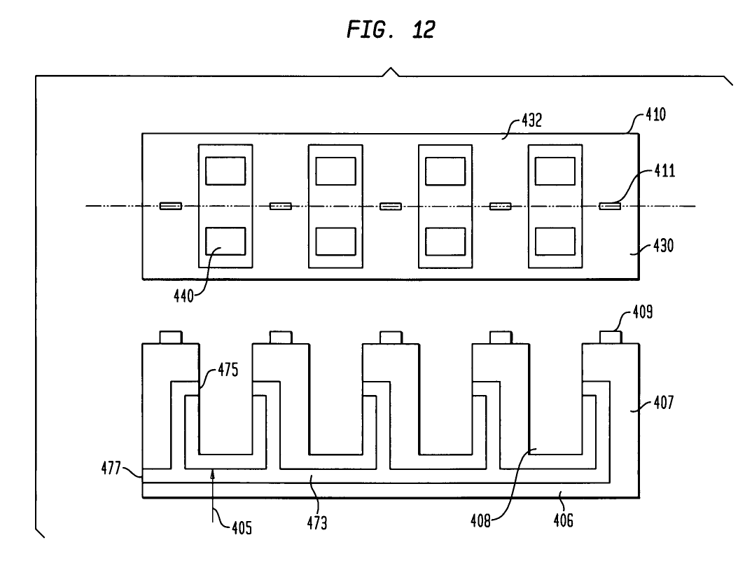

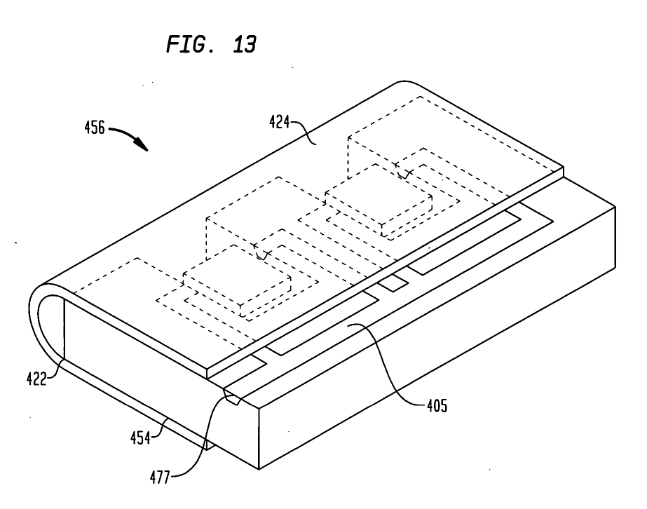

The embodiment of FIGS. 12 and 13 is similar to that of FIG. 11, except that separator element 405 is a mold plate which is adapted to provide routes for the encapsulant material to enter into pocket 454 after substrate 410 is folded upon itself. Similar to separator 305, separator 405 may include extensions 409 for mating with slots 411 of substrate 410. Once separator element 405 is positioned correctly, substrate 410 may be folded back upon itself so that second region 424 faces microelectronic elements 440 disposed on first region 422.

Separator 405 includes channels or pathways 473 extending through column 406 and extending along branches 407 to openings 475 in communication with channels 473. Channels 473 desirably are in the form of slots open to a face of the separator element. Openings 475 communicate with the spaces between the branches. When in position, at least some of the openings 475 are in communication with pocket 454 formed by the folding of the substrate, as described herein. Mold plate 471 enables encapsulant material to be introduced into pocket 454. Specifically, encapsulant material enters a gate 477 of the mold plate that is accessible to the outside environment. The encapsulant material is allowed to flow through mold plate 471 via channels 473 and into pocket 454 through openings 475.

Once the encapsulant material has been introduced into the pocket, the separator element may be removed from the folded assembly 456 of FIG. 13. A portion or the entire separator element 405 may alternatively remain a part of the folded structure 456. As with previous embodiments, although not shown, folded structure 456 may be severed at various parts so as to create individual units having at least one microelectronic element disposed within a pocket.

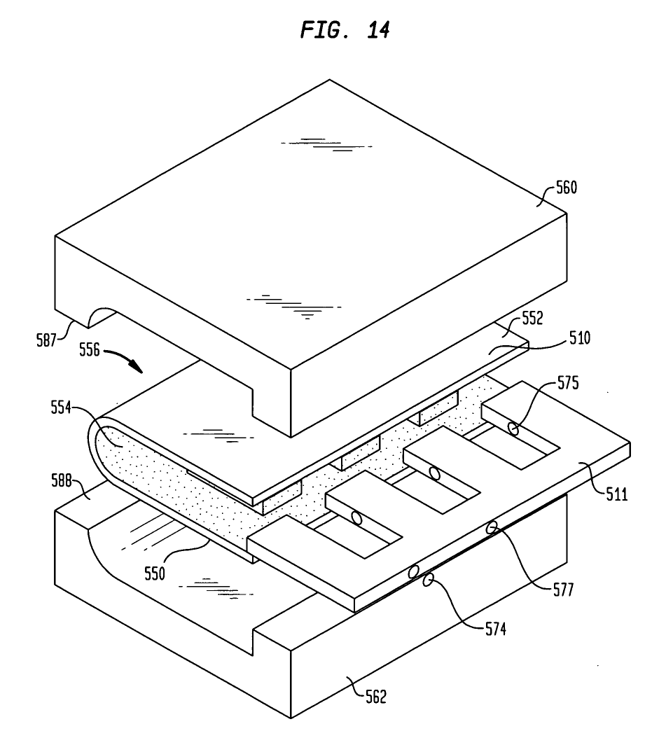

The mold plate may also be utilized in conjunction with the various mold elements previously described herein. For instance, as shown in FIGS. 14 and 15, mold plate 571 may be positioned between first run 550 and second run 552 either prior to folded structure 556 being formed or after the folder structure is formed. Of course, if the mold plate is positioned prior to folding the substrate, the mold plate will overlay either first region 522 or second region 524. As shown in this embodiment, mold plate 571, although still being used as a separator element i.e., being intermediate the first and second run, is not required to maintain a predetermined distance between first run 550 and second run 552. Once mold plate 571 is positioned within folded structure 556, mold elements may be utilized to maintain the C-shape of the folded structure while encapsulant material 470 is allowed to flow into pocket 554. The mold elements may include first mold element 560 and second mold element 562.

A perspective cross-section of the mold elements 560, 562 is shown in FIG. 14. The mold elements not only preferably tightly abut first run 550 and second run 552 when folded structure 556 is placed within cavity 564 created by the joining of the two mold elements, but the mold elements preferably tightly contact one another at various points such as at edges 587 and 588 of mold elements 560 and 562, respectively. This enables the mold elements 560 and 562 to provide a substantially leak proof holding device. As previously mentioned, second mold element 562 may include at least one pathway 574. Pathway 574 is preferably aligned with a gate 577 of mold plate 571 when the mold elements are assembled together with the folded structure. Pathway 574 enables the encapsulant material to be introduced through the mold elements and into mold cavity 571 via gate 577. Once the encapsulant material enters the mold cavity, the encapsulant material may be urged through various pathways, channels and apertures as described with reference to FIGS. 12 and 13, until finally reaching pocket 554.

In an alternate embodiment, as shown in FIG. 15, first mold element 660 and second mold element 662 may have edges 691 and 692, respectively, which abut mold plate 671 when the mold elements are assembled to the fold structure. The cavity (not shown) created by the joining of mold elements 660, 662 house a folded structure as described herein. Edge 691 may abut a top surface 697 of mold plate 671 and edge 692 may abut a lower surface 698 of the mold plate. This preferably enables edge 699 of mold plate 671 to be externally accessed, i.e., from the outside environment even after the mold elements have been joined together. Mold plate 671 may include a gate or plurality of gates 677, which lead into the channels and pathways (not shown in the drawing) of the mold plate. Encapsulant material is introduced through gates 677 and into the mold plate 671 to be dispersed through openings (not shown) of the mold plate 671 and into the pocket (not shown). Although access to mold plate 671 and, specifically, gates 677 are illustrated as being at a back edge 699 of the mold plate it would be equally applicable to provide access to a side surface of the mold plate in order to urge the encapsulant material into the pocket of the folded structure.

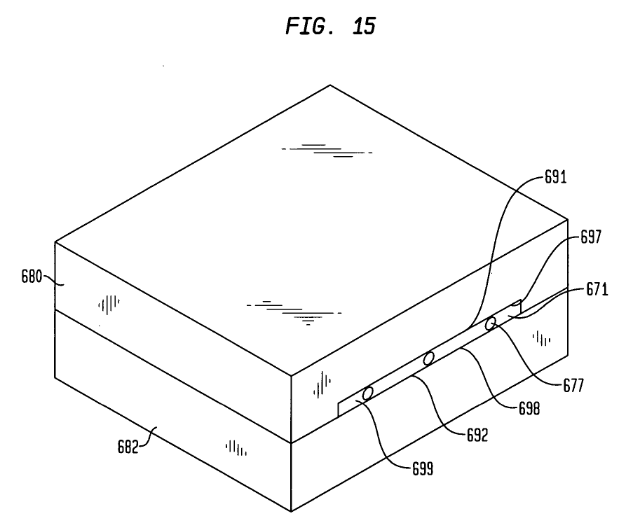

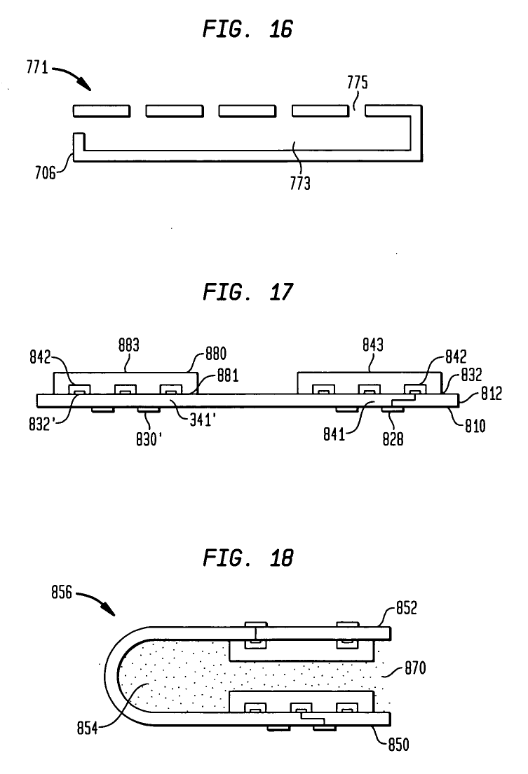

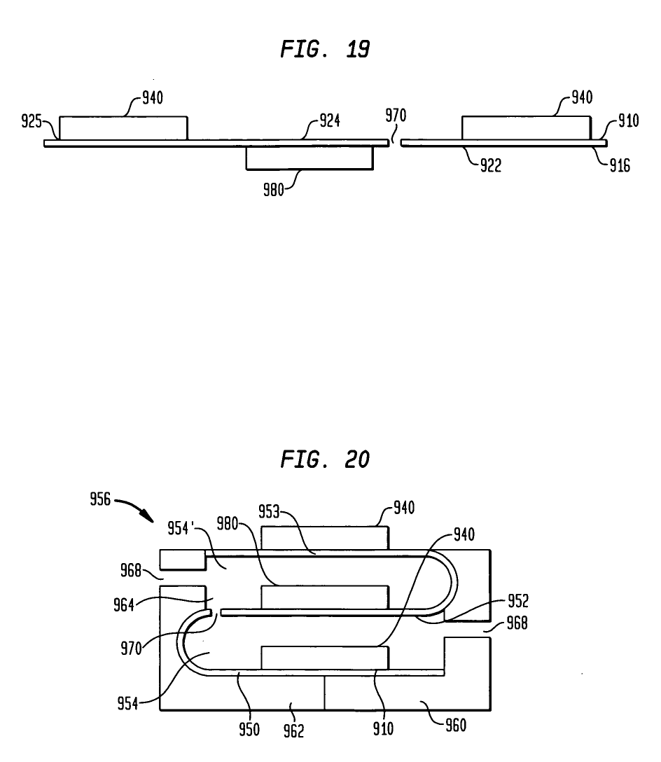

In a further aspect of the present invention, the mold plate may not require various branches and extensions. As shown in FIG. 16, mold plate 771 may include a column 706 having a channel 773 and preferably a plurality of openings 775, although only one opening is required. Mold plate 771, as discussed in conjunction with additional mold plate described herein, may be placed within or adjacent a pocket formed by the folding of a substrate. An encapsulant material is allowed to flow through the mold plate and into the pocket of a folded structure. In a preferred embodiment, at least one opening 775 is disposed within or adjacent to each section of the folded structure to allow a more even distribution of the encapsulant material.

In an alternate embodiment of the present invention, microelectronic elements may be disposed on both the first region and the second region. As shown in FIGS. 17 and 18, substrate 810 may have first microelectronic elements 840 and second microelectronic elements 880 disposed thereon. First microelectronic element 840 are disposed within first region 822 of substrate 810 and second microelectronic elements are disposed within second region 224 of the substrate. First microelectronic element 840 each include a front face 841 with contacts 842 exposed thereon and an oppositely directed rear face 843. Each second microelectronic element also includes include a front face 881 having contacts 842′ exposed thereon and an oppositely directed rear face 883. Similar to previous embodiments substrate 810 also includes dielectric layer 812, conductive connection elements 832, mounting terminals 828, and interconnect terminals 830. The terminals and connection elements are electrically connected to one another as earlier described herein. First and second microelectronic elements 840 and 880 may also be electrically connected to various terminals and connection elements as earlier described. Specifically, contacts 842′ may be electrically connected to conductive connection elements 832′ disposed in second region 824 as, for example, by bonding the contacts of microelectronic elements 880 using a bond material such as a solder. Desirably, at least some of the connection elements 832′ are connected to at least some of the mounting terminals 828.

With the microelectronic elements 840, 880 correctly positioned on substrate 810, the substrate may be folded back on itself to form a C-shape folded structure 856, as shown in FIG. 18. Folded structure 856 includes a first run 850 and a second run 852. Second run 852 overlays first run 850 to form pocket 854 therebetween. In a preferred embodiment, rear face 883 of each second microelectronic element 880 is directed towards rear face 443 of first microelectronic elements 840. While maintaining the shape of folded structure 856 and with both sets of microelectronic elements disposed within pocket 854, an encapsulant material 870 is allowed to flow within pocket 854 using any method as described herein. Encapsulant material 870 preferably flows around the perimeters of the microelectronic elements and fills most of, if not all of, the empty space within the pocket. Encapsulant material 870 is then allowed to cure so as to bond first run 850 to second run 852, first microelectronic elements 840 to second microelectronic elements 880 or both. The encapsulant material may also bond the microelectronic elements to the various runs.

In yet another alternate embodiment, substrate 910 includes first microelectronic elements 940 and second microelectronic elements 980. Substrate 910 includes a first region 922, second region 924 and third region 925. First microelectronic elements 940 are disposed on first region 922 and third region 925 while second microelectronic elements 980 are disposed on second region 924. Substrate 910 also includes an upper surface 914 and a lower surface 916. For ease of illustration, connection elements, terminals and various other electrically conducting elements are not illustrated in the figure. However, it should be understood that substrate 910 includes various conducting elements as so forth as described herein and may include various other elements by those known in the art. For instance, the only difference between second microelectronic elements 980 and second microelectronic elements 880 illustrated in FIGS. 17 and 18, may be that second microelectronic elements 980 are electrically connected to a lower surface 916 of the substrate as opposed to an upper surface.

Substrate 910 may be folded to form an S-shape folded structure 956. One method of forming such S-shape configuration is shown in U.S. patent application Ser. No. 10/448,515, the disclosure of which is hereby incorporated by reference herein. Folded structure 956 includes first run 950, second run 952 and third run 953. Second run 952 overlays first run 950 to form pocket 954 and third run 953 overlays second run 952 to form pocket 954′. Once the S-shape folded structure 956 is formed various molds may be placed against the folded structure to not only temporarily maintain the S-shape of the structure but to also allow the delivery of an encapsulant material into pockets 954 and 954′. For instance, as shown in FIG. 20, first mold element 960 and second mold element 962 may be joined together to form cavity 964, in which folded structure 956 is disposed. Either first mold element 960, second mold element 962 or both may include at least one opening 968. Opening 968 is in communication with pocket 954, 954′ or both and enables an encapsulant material to flow from outside the folded structure 956 to within the pockets. In one variation of the present embodiment, substrate 910 may include at least one aperture 970 extending from upper surface 914 to lower surface 916. Aperture 970 helps to disburse any introduced encapsulant material throughout folded structure 956 by placing pocket 954 and pocket 9541 in communication with each other. Thus the encapsulant material is able to flow from one pocket to the other pocket. In a preferred embodiment, the encapsulant material is provided to folded structure 956 in order to fill most of if not all of the empty space within pocket 954 and pocket 954′.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of making a microelectronic assembly comprising the steps of:
depositing one or more microelectronic elements onto a flexible substrate;
folding said substrate into a folded state so that a first region of said substrate forms a first run and a second region of said substrate forms a second run overlaying said first run, said first run and said second run forming a pocket therebetween, said one or more microelectronic elements being disposed in said pocket;
temporarily maintaining said folded state while providing an encapsulant material into said pocket; and
curing said encapsulant material so that said cured encapsulant material holds said flexible substrate in said folded state.

2. The method according to claim 1, wherein said encapsulant material bonds said microelectronic elements to said second run.

3. The method according to claim 2, wherein the only element bonding said microelectronic element to said second run is said encapsulant material.

4. The method according to claim 1, wherein said step of folding said substrate includes providing a separator element, said separator element overlying said first region of said substrate, wherein said flexible substrate is folded about said separator element so that at least a portion of said separator element is disposed in said pocket when said substrate is in said folded state.

5. The method according to claim 4, wherein said step of providing said separator element includes providing a mold plate having at least one runner channel and at least one aperture, so that after said folding step said runner channel is in communication with said pocket through said at least one aperture, and wherein the step of providing an encapsulant material includes urging said encapsulant material through said runner channel and said aperture and into said pocket.

6. The method according to claim 5, wherein said substrate includes openings, wherein said separator element includes extensions and said folding step includes engaging said extensions with said openings.

7. The method according to claim 5, wherein said mold plate includes a column and a plurality of branches projecting from said column, wherein at least some of said microelectronic elements are separated from one another by one of said branches of said mold plate, said at least one runner channel including channels extending within said branches, said at least one aperture including apertures disposed on said branches remote from said column.

8. The method according to claim 5, wherein the step of maintaining said substrate in said folded state includes disposing said substrate between opposed mold elements, at least one of said mold elements including an inlet channel, and said step of urging said encapsulant material includes urging said encapsulant material through said inlet channel into said runner channel.

9. The method according to claim 4, wherein at least a portion of said separator element remains integral with the microelectronic assembly.

10. The method according to claim 1, wherein the step of maintaining said substrate in said folded state includes disposing said substrate between opposed mold elements, at least one of said mold elements including an inlet channel having a first end and a second end, said first end being open to the outside environment and said second end being in communication with said pocket.

11. The method according to claim 1, wherein said step of maintaining said substrate in said folded state includes disposing said substrate in between mold elements.

12. The method according to claim 1, wherein the step of providing said encapsulant material includes providing at least one aperture extending from a first surface of said substrate to a second surface of said substrate so that said aperture is in communication with said pocket, wherein said encapsulant material is provided into said pocket through said aperture.

13. The method according to claim 12, wherein the step of maintaining said substrate in said folded state includes disposing said substrate between mold elements, at least one of said mold elements including an inlet channel having a first end and a second end, said first end being in communication with said outside environment and said second end being in communication with said aperture of said substrate, wherein said step of providing said encapsulant material includes urging said encapsulant material through said inlet channel.

14. The method according to claim 1, wherein said microelectronic elements include front surfaces having contacts exposed thereon, and wherein the step of depositing said microelectronic elements includes positioning said microelectronic elements so that said front surface faces said first region.

15. The method according to claim 1, wherein said microelectronic elements include front surfaces having contacts exposed thereon, wherein the step of depositing said microelectronic elements includes positioning said microelectronic elements so that said front surface faces away from said first region.
